(19) United States
(12) Patent Application Publication
(10) Pub. No.: US 2013/0062578 A1
(43) Pub. Date: Mar. 14, 2013

(54) DIELECTRIC COMPOSITION, METHOD OF FABRICATING THE SAME, AND MULTILAYER CERAMIC ELECTRONIC COMPONENT USING THE SAME

(71) Applicants: Kum Jin PARK, Suwon (KR); Chang Hak CHOI, Suwon (KR); Jong Hoon YOO, Seoul (KR); Chang Hoon KIM, Yongin (KR); Hyung Joon JEON, Suwon (KR); Hye Young BAEG, Suwon (KR)

(72) Inventors: Kum Jin PARK, Suwon (KR); Chang Hak CHOI, Suwon (KR); Jong Hoon YOO, Seoul (KR); Chang Hoon KIM, Yongin (KR); Hyung Joon JEON, Suwon (KR); Hye Young BAEG, Suwon (KR)

(73) Assignee: SAMSUNG ELECTRO-MECHANICS CO., LTD.

(21) Appl. No.: 13/335,255

(22) Filed: Dec. 22, 2011

(30) Foreign Application Priority Data
Sep. 8, 2011 (KR) 10-2011-0091232

(51) Int. Cl. H01G 4/12; H01C 7/10; H01C 7/13; C04B 35/468; B05D 5/12; H01F 5/00; H01L 41/00; B82Y 40/00; B82Y 30/00

(52) U.S. Cl. 252/512; 361/321.2; 336/200; 338/20; 338/22 R; 310/311; 252/520.21; 427/126.1; 427/126.3; 427/58; 427/123; 977/773; 977/896; 977/932

(57) ABSTRACT

There are provided a dielectric composition, a method of fabricating the same, and a multilayer ceramic electronic component using the same. The dielectric composition includes a perovskite powder particle having a surface on which a doping layer is formed, the doping layer being doped with at least one material selected from a group consisting of alkaline earth elements and boron group elements, and rare earth elements.

When a perovskite powder particle is synthesized by using a hydrothermal synthesis method, a doping layer doped with at least one material selected from the group consisting of alkaline earth elements and boron group elements and rare earth elements is formed on a surface of the perovskite powder particle, such that a dielectric composition having excellent reliability, dielectric properties, and electric properties can be fabricated.

### CROSS-REFERENCE TO RELATED APPLICATIONS

This application claims the priority of Korean Patent Application No. 10-2011-0091232 filed on Sep. 8, 2011, in the Korean Intellectual Property Office, the disclosure of which is incorporated herein by reference.

### BACKGROUND OF THE INVENTION

1. Field of the Invention

The present invention relates to a dielectric composition having excellent dielectric properties and electric properties, a method of fabricating the same, and a multilayer ceramic electronic component using the same.

2. Description of the Related Art

A perovskite powder particle, a ferroelectric ceramic material, has been used as a raw material for electronic components such as a multilayer ceramic capacitor (MLCC), a ceramic filter, a piezoelectric element, a ferroelectric memory, a themistor, a varistor, and the like.

Barium titanate (BaTiO₃), a high dielectric material having a perovskite structure, has been used as a dielectric material for a multilayer ceramic capacitor.

Recently, with the trend for slimness and smallness, high capacitance, high reliability, and the like, of electronic components, a ferroelectric particle is required to have a small size and excellent dielectric constant and reliability.

If the diameter of a barium titanate powder particle, a main component of a dielectric layer, is large, surface roughness of the dielectric layer may be increased, and thus an electric short ratio may be increased and insulation resistance may be defective.

For this reason, the barium titanate powder particle, a main component, is requested to be grain-refined.

However, in a case in which a barium titanate powder particle is grain-refined, a tetragonal ratio thereof may be reduced. Therefore, it is necessary that this crystalline problem be overcome and a high crystalline fine-grain barium titanate powder particle be developed.

A solidification method and a wet method may be used in the fabrication of this perovskite powder particle, and further, an oxalate precipitation method, a hydrothermal synthesis method, and the like may be used in the wet method.

According to the solidification method, the minimal size of normal powder particles is about 1 micron, significantly large, and the size of the particle is difficult to control. Furthermore, the particles may agglomerate, and pollution may occur at the time of sintering. Therefore, it is difficult to make a fine grained perovskite powder particle.

A phenomenon in which tetragonality drops as the dielectric particles become smaller generally occurs in several methods, and if the dielectric particles are decreased to 100 nm or less, it is very difficult to secure the crystalline axis ratio (c/a).

Furthermore, dispersion becomes more difficult as the size of powder particles is reduced. Therefore, finer-grain powder particles are required to have higher dispersibility.

In addition, finer grains may lead to rapid grain growth, and thus, it is difficult to obtain a dielectric layer having a uniform fine structure and to secure high electric reliability in an electronic component, a final product.

Furthermore, as the dielectric particle is smaller, an additive is more difficult to be dispersed, and solidification of the additive occurs nonuniformly and easily, which may cause a reduction in dielectric constant.

### SUMMARY OF THE INVENTION

An aspect of the present invention provides a dielectric composition having excellent dielectric properties and electric properties, a method of fabricating the same, and a multilayer ceramic electronic component using the same.

According to an aspect of the present invention, there is provided a dielectric composition, including a perovskite powder particle having a surface on which a doping layer is formed, the doping layer being doped with at least one material selected from a group consisting of alkaline earth elements and boron group elements, and rare earth elements.

An average thickness of the doping layer may be 0.1 to 10% of a diameter of the perovskite powder particle.

A standard deviation of an average thickness of the doping layer may be 10% or less of a diameter of the perovskite powder particle.

The at least one material selected from a group consisting of alkaline earth elements and boron group elements and the rare earth elements, may be at least one selected from a group consisting of nitrate, acetate, hydroxide, chloride, and perchlorate.

The rare earth elements may be at least one selected from a group consisting of yttrium (Y), gadolinium (Gd), dysprosium (Dy), holmium (Ho), europium (Eu), erbium (Er) and ytterbium (Yb).

The alkaline earth elements may be at least one selected from a group consisting of magnesium (Mg) and calcium (Ca).

The boron group elements may be at least one selected from a group consisting of boron (B), aluminum (Al), gallium (Ga) and indium (In).

The perovskite powder particle may be at least one selected from the group consisting of BaTiO₃, BaTiₓZr₁₋ₓO₃, BaₓY₁₋ₓTiO₃, BaₓDy₁₋ₓTiO₃, and BaₓHo₁₋ₓTiO₃ (0<x<1).

According to another aspect of the present invention, there is provided a method of fabricating a dielectric composition, the method including: mixing a metal salt and a metal oxide to form a perovskite particle nucleus; hydrothermally treating the perovskite particle nucleus to form a slurry; mixing a solution in which at least one material selected from a group consisting of alkaline earth elements and boron group elements and rare earth elements are dissolved, into the slurry, and stirring the mixed solution; and heating the mixed solution to obtain a perovskite powder particle having a surface on which a doping layer is formed, the doping layer being doped with the at least one material selected from a group consisting of alkaline earth elements and boron group elements and the rare earth element.

An average thickness of the doping layer may be 0.1 to 10% of a diameter of the perovskite powder particle.

A standard deviation of an average thickness of the doping layer may be 10% or less of a diameter of the perovskite powder particle.

The at least one material selected from a group consisting of alkaline earth elements and boron group elements and the rare earth elements, may be at least one selected from a group consisting of nitrate, acetate, hydroxide, chloride, and perchlorate.

The rare earth elements may be at least one selected from a group consisting of yttrium (Y), gadolinium (Gd), dysprosium (Dy), holmium (Ho), europium (Eu), erbium (Er) and ytterbium (Yb).

The alkaline earth elements may be at least one selected from a group consisting of magnesium (Mg) and calcium (Ca).

The boron group elements may be at least one selected from a group consisting of boron (B), aluminum (Al), gallium (Ga), and indium (In).

The perovskite powder particle may be at least one selected from a group consisting of BaTiO₃, BaTiₓZr₁₋ₓO₃, BaₓY₁₋ₓTiO₃, BaₓDy₁₋ₓTiO₃, and BaₓHo₁₋ₓTiO₃ (0<x<1).

The doping layer and the perovskite powder particle may have the same crystal lattice.

The at least one material selected from a group consisting of alkaline earth elements and boron group elements and the rare earth elements may have a content of 0.00001 to 3.0 parts by weight, based on 100 parts by weight of the perovskite powder particle.

According to another aspect of the present invention, there is provided a multilayer ceramic electronic component, including: a ceramic main body including a dielectric layer; and inner electrode layers disposed to face each other with the dielectric layer therebetween within the ceramic main body, wherein the dielectric layer includes a plurality of dielectric grains each having a surface on which a doping layer is formed, the doping layer being doped with at least one material selected from a group consisting of alkaline earth elements and boron group elements and rare earth elements.

An average thickness of the doping layer may be 0.1 to 10% of a diameter of each dielectric grain.

A standard deviation of an average thickness of the doping layer may be 10% or less of a diameter of each dielectric grain.

The rare earth elements may be at least one selected from a group consisting of yttrium (Y), gadolinium (Gd), dysprosium (Dy), holmium (Ho), europium (Eu), erbium (Er) and ytterbium (Yb).

The alkaline earth elements may be at least one selected from a group consisting of magnesium (Mg) and calcium (Ca).

The boron group elements may be at least one selected from a group consisting of boron (B), aluminum (Al), gallium (Ga), and indium (In).

Each dielectric grain may be at least one selected from a group consisting of BaTiO₃, BaTiₓZr₁₋ₓO₃, BaₓY₁₋ₓTiO₃, BaₓDy₁₋ₓTiO₃, and BaₓHo₁₋ₓTiO₃ (0<x<1).

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a view schematically showing a dielectric composition according to an embodiment of the present invention;

FIG. 2 is a flow chart showing a process of fabricating the dielectric composition according to an embodiment of the present invention;

FIG. 3 is a perspective view schematically showing a multilayer ceramic capacitor according to an embodiment of the present invention;

FIG. 4 is a cross-sectional view taken along line A-A′ of FIG. 3;

FIG. 5 is a scanning transmission electron microscope (STEM) photograph of a barium titanate powder according to an embodiment of the present invention;

FIG. 6 is a graph showing component analysis of region B of FIG. 5; and

FIG. 7 is a high resolution transmission electron microscope (HRTEM) photograph of the barium titanate powder according to an embodiment of the present invention.

### DETAILED DESCRIPTION OF THE PREFERRED EMBODIMENT

Embodiments of the present invention will now be described in detail with reference to the accompanying drawings. Embodiments of the present invention may be modified in many different forms and the scope of the invention should not be limited to the embodiments set forth herein. The embodiments of the present invention are provided so that those skilled in the art may more completely understand the present invention. In the drawings, the shapes and dimensions may be exaggerated for clarity, and the same reference numerals will be used throughout to designate the same or like components.

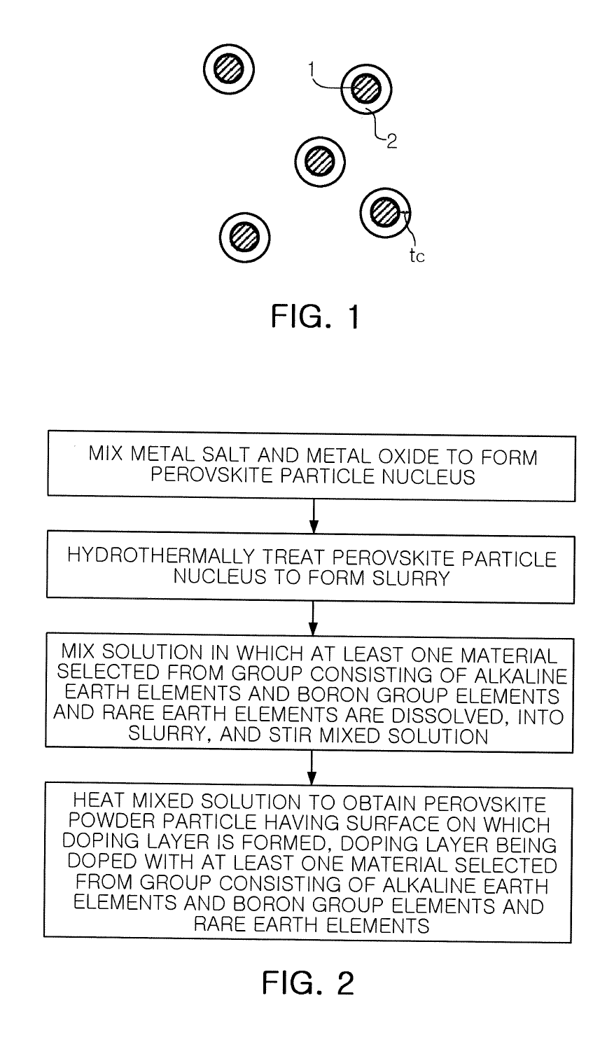

FIG. 1 is a view schematically showing a dielectric composition according to an embodiment of the present invention.

Referring to FIG. 1, a dielectric composition according to an embodiment of the present invention may include a perovskite powder particle 1 having a surface on which a doping layer 2 is formed. The doping layer is doped with at least one material selected from the group consisting of alkaline earth elements and boron group elements and rare earth elements.

The perovskite powder particle 1 may be, but not limited thereto, for example, at least one selected from the group consisting of BaTiO₃, BaTiₓZr₁₋ₓO₃, BaₓY₁₋ₓTiO₃, BaₓDy₁₋ₓTiO₃, and BaₓHo₁₋ₓTiO₃ (0<x<1).

Hereinafter, the perovskite powder particle according to the embodiment of the present invention, especially a barium titanate (BaTiO₃) powder particle will be described, but the present invention is not limited thereto.

According to the embodiment of the present invention, the perovskite powder particle 1, which may be barium titanate (BaTiO₃) powder particle fabricated by a hydrothermal synthesis method, has a surface on which the doping layer 2 is formed. The doping layer 2 may be doped with at least one material selected from the group consisting of alkaline earth elements and boron group elements and rare earth elements. Therefore, the perovskite powder particle 1, which may be a barium titanate (BaTiO₃) powder particle, may have very excellent dielectric constant and electric properties.

The at least one material selected from the group consisting of alkaline earth elements and boron group elements and the rare earth elements are not particularly limited, but for example, may be at least one selected from the group consisting of nitrate, acetate, hydroxide, chloride, and perchlorate.

The rare earth elements are not particularly limited, but for example, may be at least one selected from the group consisting of yttrium (Y), gadolinium (Gd), dysprosium (Dy), holmium (Ho), europium (Eu), erbium (Er) and ytterbium (Yb).

When the rare earth elements are added to the perovskite powder particle having an ABO₃ structure, an element at site A or B may be substituted with the rare earth elements.

The alkaline earth elements are not particularly limited, but may be at least one selected from the group consisting of magnesium (Mg) and calcium (Ca). The boron group elements are not particularly limited, but for example, may be at least one selected from the group consisting of boron (B), aluminum (Al), gallium (Ga), and indium (In).

When the at least one selected from the group consisting of alkaline earth elements and boron group elements is added to the perovskite powder particle having an ABO₃ structure, an element at site B may be substituted with it.

When only the rare earth elements are added as a doping material for forming the doping layer, it is difficult to form the doping layer to have a small thickness. While the formation of the doping layer may be difficult when only the alkaline earth elements and boron group elements are added.

In the dielectric composition according to the embodiment of the present invention, both the at least one selected from the group consisting of alkaline earth elements and boron group elements and the rare earth elements are added to form the doping layer, whereby a doping layer having a significantly reduced thickness may be formed on a powder particle surface to allow for improvements in electric properties of an electronic component using the same.

According to the embodiment of the present invention, the doping layer 2 may have an average thickness (tc), which is 0.1 to 10% of a diameter of the perovskite powder particle 1.

The measurement of the average thickness (tc) of the doping layer 2 is not particularly limited. The average thickness (tc) of the doping layer be determined as an average of thickness values measured at several points of the doping layer 2 formed on the surface of the perovskite powder particle 1. It may be determined by individually measuring average thicknesses of the doping layers 2 formed on any ten powder particles and calculating an average of the measured average thicknesses.

A measurement method and a measurement result with respect to the thickness of the doping layer 2 will be described in detail later.

In general, the perovskite powder particle may be homogeneously mixed with an additive powder particle to be sintered at a high-temperature reducing atmosphere, in order to realize properties of a multilayer ceramic electronic component, especially, a multilayer ceramic capacitor.

Here, a doping reaction may occur between the additive powder particle and the perovskite powder particle, to form a doping layer of the additive powder particle on a surface of the perovskite powder particle. The doping layer may function to realize temperature characteristics and reliability.

Meanwhile, the doping layer may be positive in reliability and temperature characteristics, but lead to a degradation in dielectric constant.

Especially, in a case in which the perovskite powder particle is small, the additive powder particle needs to have a reduced size. In this case, dispersion may be more difficult to cause difficulty in the formation of the doping layer having a uniform and reduced thickness.

A coating layer may be formed in order to solve the above defects. However, in the coating layer, a combination due to a chemical or physical adsorption of different kinds of elements, a binding structure thereof may be broken during a dispersion or sintering process, or residual organic materials, which are added for forming the coating layer may have adverse effects.

According to the embodiment of the present invention, the average thickness (tc) of the doping layer 2 may be 0.1 to 10% of the diameter of the perovskite powder particle 1, and thus, a doping layer having a uniform and reduced thickness may be formed.

Especially, according to the embodiment of the present invention, a standard deviation of the average thickness of the doping layer 2 may have be 10% or less of the diameter of the perovskite powder particle 1.

In other words, the doping layer 2 may be formed by doping the surface of the perovskite powder particle 1 very thinly and uniformly, and thus, the standard deviation of the thickness thereof may be 10% or less as above.

Further, since the perovskite powder particle 1 and the doping layer 2 may have the same crystal orientation, the doping layer may not be damaged during processing. Thus, an electronic component to which the dielectric composition according to the embodiment of the present invention is applied may have excellent reliability, temperature characteristics, and dielectric constant.

Further, economical salt may be used instead of using an expensive ultrafine grained oxide and the amount of additive may be significantly decreased, whereby production costs may be reduced. In addition, doping is performed by adding the additive during a hydrothermal synthesis process, to allow for a simplified process.

Meanwhile, when the average thickness (tc) of the doping layer 2 is below 0.1% of the diameter of the perovskite powder particle 1, reliability and temperature characteristics may have inadequacies. when the average thickness (tc) of the doping layer 2 is greater than 10%, the dielectric constant thereof may be reduced.

FIG. 2 is a flow chart showing a process of fabricating the dielectric composition according to an embodiment of the present invention.

Referring to FIG. 2, a method of fabricating a dielectric composition according to an embodiment of the present invention may include: mixing a metal salt and a metal oxide to form a perovskite particle nucleus; hydrothermally treating the perovskite particle nucleus to form a slurry; mixing a solution in which at least one material selected from the group consisting of alkaline earth elements and boron group elements and rare earth elements are dissolved, into the slurry, and stirring the mixed solution; and heating the mixture solution to obtain a perovskite powder particle having a surface on which a doping layer is formed, the doping layer being doped with the at least one material selected from the group consisting of alkaline earth elements and boron group elements and the rare earth elements.

Hereinafter, a process of fabricating the dielectric composition according to the embodiment of the present invention will be described in detail according to respective steps thereof.

The perovskite powder particle is a powder having an ABO₃ structure. In the embodiment of the present invention, the metal oxide is an element supply source corresponding to site B and the metal salt is an element supply source corresponding to site B.

First, the metal salt and the metal oxide are mixed to form a perovskite particle nucleus.

The metal oxide may be at least one selected from the group consisting of titanium (Ti) and zirconium (Zr).

In the case of titania and zirconia, hydrolysis thereof may be facilitated. Thus, they may be precipitated in a gel type of water containing titanium or water containing zirconium when they are mixed with pure water, without a separate additive.

The water containing metal oxide may be washed to remove impurities therefrom.

More specifically, the water containing metal oxide is filtered by pressure to remove a residual solution therefrom, and then filtered with pure water being poured therein to remove impurities existing on the surface of the particle.

Next, pure water and acid or base may be added to the water containing metal oxide.

Pure water is put into the water containing metal oxide powder obtained, and then stirring is performed by using a high-viscosity stirrer at a temperature maintained 0° C. to 60° C. for 0.1 to 72 hour, thereby preparing a water containing metal oxide slurry.

Acid or base may be added to the prepared slurry. The acid or base is used as a deflocculant, and 0.00001 to 0.2 moles of the acid or base, based on the content of the water metal containing metal oxide may be added. The acid is not particularly limited as long as it is general. Examples thereof may include hydrochloric acid, nitric acid, sulfuric acid, phosphoric acid, formic acid, acetic acid, polycarboxylic acid, and the like, and these alone may be used or at least two thereof may be mixed to be used.

The base is not particularly limited as long as it is general. Examples thereof may include tetramethyl ammonium hydroxide, tetraethylammonium hydroxide, and the like, and these may be used alone or mixing together.

The metal salt may be barium hydroxide or a mixture of rare earth salt and barium hydroxide.

The rare earth salt is not particularly limited, and, for example, yttrium (Y), dysprosium (Dy), holmium (Ho), or like may be used.

The forming of the perovskite particle nucleus may be performed at 60° C. to 150° C.

Next, the perovskite particle nucleus is put into a hydrothermal reactor and hydrothermally treated, thereby forming a slurry. Then, a solution in which the at least one material selected from the group consisting of alkaline earth elements and boron group elements and the rare earth elements are dissolved, may be mixed into the slurry, and the mixed solution may be stirred.

Finally, the mixed solution is heated to obtain a perovskite powder particle. The perovskite powder particle has a surface on which a doping layer is formed, the doping layer being doped with the at least one material selected from the group consisting of alkaline earth elements and boron group elements and the rare earth elements.

The at least one material selected from the group consisting of alkaline earth elements and boron group elements and the rare earth elements may be at least one selected from the group consisting of nitrate, acetate, hydroxide, chloride, and perchlorate.

The doping layer and the perovskite powder particle have the same crystal lattice.

The at least one material selected from the group consisting of alkaline earth elements and boron group elements and the rare earth elements may have a content of 0.00001 to 3.0 parts by weight based on 100 parts by weight of the perovskite powder particle, but the content thereof is not particularly limited.

If the content is below 0.00001 parts by weight, the formation of the doping layer is not sufficient, which may cause defects in reliability and temperature characteristics. If the content is greater than 3.0 parts by weight, the dielectric constant of the doping layer may be deteriorated.

Since the other characteristics of the doping layer are the same as those of the dielectric composition according to the embodiment of the present invention, descriptions thereof will be omitted.

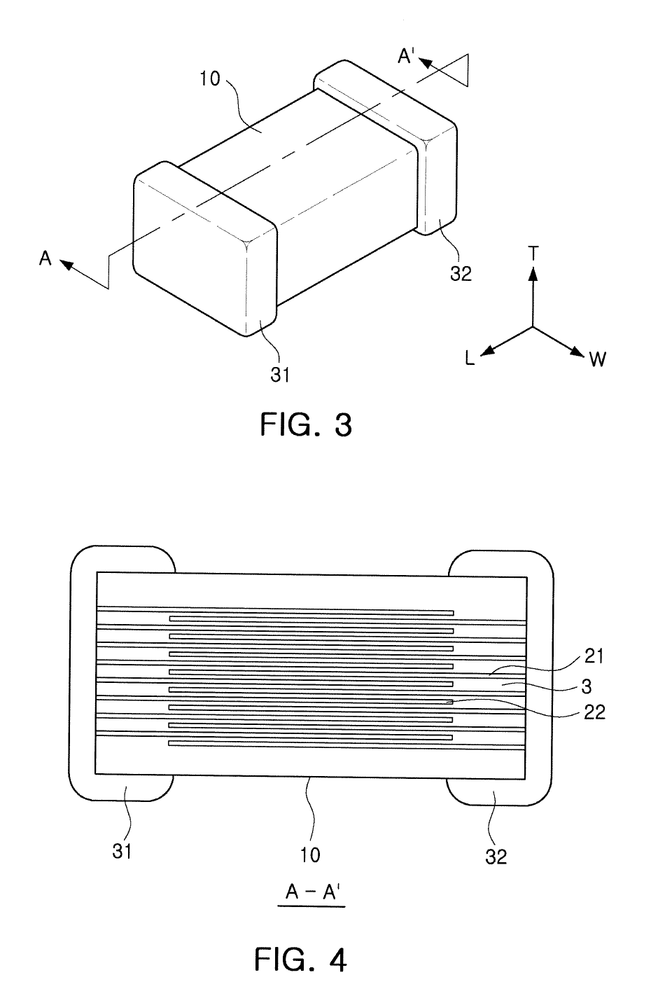

FIG. 3 is a perspective view schematically showing a multilayer ceramic capacitor according to an embodiment of the present invention.

FIG. 4 is a cross-sectional view taken along line A-A′ of FIG. 3.

Referring to FIGS. 3 and 4, a multilayer ceramic electronic component according to an embodiment of the present invention may include a ceramic main body 10 including a dielectric layer 3; and inner electrode layers 21 and 22 disposed to face each other with the dielectric layer 3 therebetween within the ceramic main body 10. The dielectric layer 3 may include a plurality of dielectric grains each having a surface on which a doping layer is formed, the doping layer being doped with at least one material selected from the group consisting of alkaline earth elements and boron group elements and rare earth elements.

Hereinafter, the multilayer ceramic electronic component according to the embodiment of the present invention, particularly, a multilayer ceramic capacitor, will be described, but the present invention is not limited thereto.

In the multilayer ceramic capacitor according to the embodiment of the present invention, ‘length direction’, ‘width direction’, and ‘thickness direction’ are respectively defined by ‘L’ direction, ‘W’ direction, and ‘T’ direction in FIG. 1. Here, the ‘thickness direction’ may be used in the same concept as a direction in which dielectric layers are laminated, that is, ‘lamination direction’.

According to the embodiment of the present invention, a raw material forming the dielectric layer 3 is not particularly limited as long as it may obtain sufficient capacitance. For example, the raw material may be barium titanate (BaTiO₃) powder particles.

The barium titanate (BaTiO₃) powder particle may have a doping layer formed on a surface thereof, the doping layer being doped with the at least one material selected from the group consisting of alkaline earth elements and boron group elements and the rare earth elements.

Thus, a dielectric composition having excellent reliability, dielectric properties, and electric properties may be fabricated.

In addition, a multilayer ceramic capacitor manufactured by using the dielectric composition may have a high dielectric constant at room-temperature and excellent insulation resistance and withstand voltage properties to thereby allow for improvements in reliability thereof.

The doping layer may have the average thickness (tc), which is 0.1 to 10% of a diameter of each dielectric grain.

The diameter of each dielectric grain may be measured by analyzing a photograph of a cross section of the dielectric layer cut in the lamination direction thereof through a scanning electron microscope (SEM). For example, an average grain size of the dielectric layer may be measured by using a grain size measurement software supporting an average grain size standard measurement method defined by American Society for Testing and Materials (ASTM) E112.

Specifically, extraction points of the dielectric grains are not particularly limited, and as shown in FIG. 4, any dielectric grains extracted from an image obtained by scanning a cross section of the ceramic main body 10 in a length-thickness (L-T) direction, which is cut at a central part of the ceramic main body 10 in the width (W) direction, through using a scanning electron microscope (SEM), may be used.

The number of dielectric grains extracted is not particularly limited. With respect to the dielectric grains, a diameter of one dielectric grain and a thickness of the entire region of the doping layer formed on a surface of the dielectric grain are individually measured, and then average values thereof may be compared with each other.

In addition, average thicknesses of doping layers formed on any ten dielectric grains are individually measured, and an average value of the measured average thicknesses may be determined as the average thickness of each doping layer.

Specifically, in a method of measuring the diameter of the dielectric grain and the average thickness of the doping layer, a boundary of the doping layer may be defined by combining a transmission electron microscope (TEM) image and an energy dispersive spectrometry (EDS) analysis with respect to the extracted dielectric grains.

The average thickness of the doping layer may be measured by carrying out an energy dispersive spectrometry (EDS) line profile several times.

The multilayer ceramic capacitor according to the embodiment of the present invention may include the plurality of dielectric grains each having a surface on which the doping layer is formed, the doping layer being doped with the at least one material selected from the group consisting of alkaline earth elements and boron group elements and the rare earth elements, such that it may have a high dielectric constant at room-temperature and excellent insulation resistance and withstand voltage properties to allow for improvements in reliability thereof.

As a material forming the dielectric layer 3 may be formed by adding various kinds of ceramic additive, an organic solvent, a plasticizer, a binder, a dispersant, or the like to powder particles, such as barium titanate (BaTiO₃) powder particles, according to objects of the present invention.

Since the other features of the present embodiment overlap the features of the dielectric composition according to the foregoing embodiment of the present invention, descriptions thereof will be omitted.

A material forming the first and second inner electrodes 21 and 22 is not particularly limited, and for example, the first and second inner electrodes 21 and 22 may be formed by using a conductive paste made of at least one of silver (Ag), lead (Pb) platinum (Pt), nickel (Ni) and copper (Cu).

The multilayer ceramic capacitor according to the embodiment of the present invention may further include a first outer electrode 31 electrically connected to the first inner electrode 21 and a second outer electrode 32 electrically connected to the second inner electrode 22.

The first and second outer electrodes 31 and 32 may be electrically connected to the first and second inner electrodes 21 and 22, so as to form capacitance, and the second outer electrode 32 and the first outer electrode 31 may be connected to different potentials.

A material forming the first and second outer electrodes 31 and 32 is not particularly limited as long as it may be electrically connected to the first and second inner electrodes 21 and 22, so as to capacitance, and for example, the material may include at least one selected from the group consisting of copper (Cu), nickel (Ni), silver (Ag), and silver-palladium (Ag—Pd).

Hereafter, the present invention will be described in detail with reference to Examples; however, present invention is not limited thereto.

### Example 1

Barium hydroxide octahydrate (Ba(OH)₂8H₂O) was put in a reactor and subjected to nitrogen purging, and then stirred and dissolved at a temperature of 70° C. or higher.

Then, after a titanium dioxide (TiO₂) sol was heated at a temperature of 40° C. or higher to be prepared, the sol was rapidly mixed with the barium solution and then stirred and reacted at 110° C.

After finishing the generation of nucleus, the slurry was moved to an autoclave. Then, the temperature of a reactor is raised to 250° C., and then grain-growth was carried out for 20 hours, thereby obtaining a barium titanate powder particle of 90 nm.

The autoclave was cooled, and when the temperature of the autoclave reaches 100° C. or lower, yttrium acetate and magnesium chloride were dissolved in pure water, and then added thereto.

Here, during the addition, a vent valve of the autoclave was opened and a raw material feed pipe was opened Stirring is continued for well mixing during the addition.

Molarity of the additive based on the barium titanate powder particle was formed such that yttrium and magnesium had concentrations of 0.6% and 0.3%, respectively.

After addition of the additive, the autoclave was again closed. Then, the temperature thereof was raised to 220° C., which was then kept for 5 hour while the grain-growth was carried out.

After lowering the temperature of the autoclave, the slurry was moved to a tank. Then, precipitation was carried out, followed by removal of supernatant liquid, and then pure water was added thereto to lower the concentration. Then, precipitation was again carried out, followed by removal of supernatant liquid. Through these procedures, barium ions (Ba²⁺) remaining in the remainder liquid of the slurry was removed, thereby setting a ratio of Ba:Ti to be 1, and then the slurry was filtered and dried, thereby obtaining a dielectric raw material powder particle.

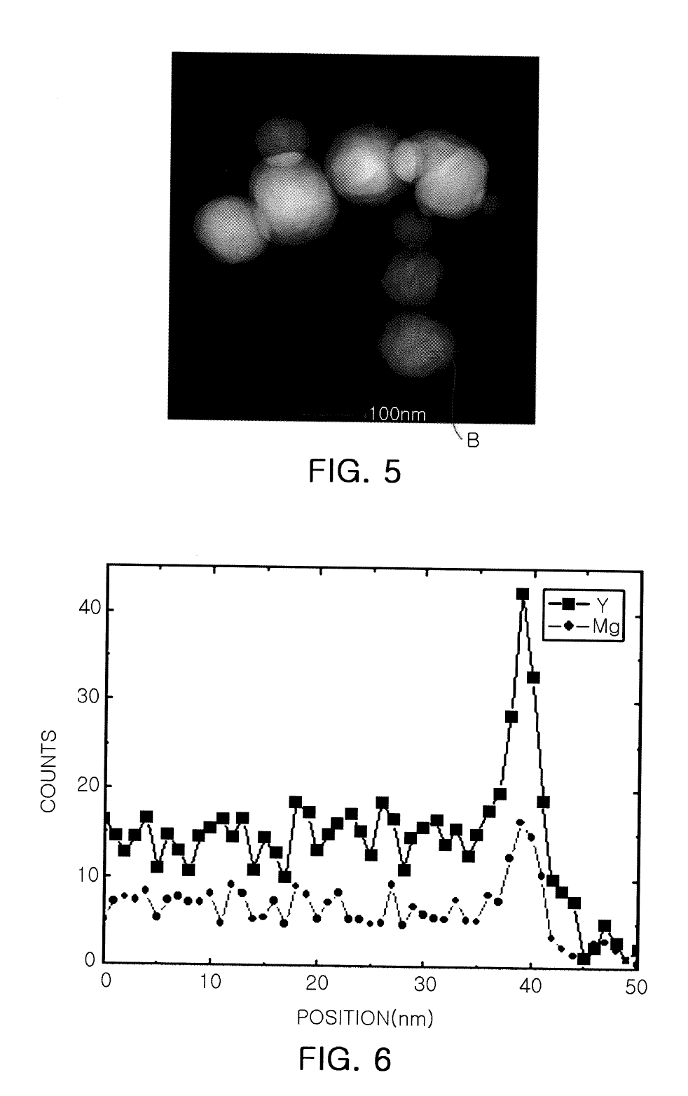

FIG. 5 is a scanning transmission electron microscope (STEM) photograph of a barium titanate powder according to an embodiment of the present invention

FIG. 6 is a graph showing component analysis of region B of FIG. 5.

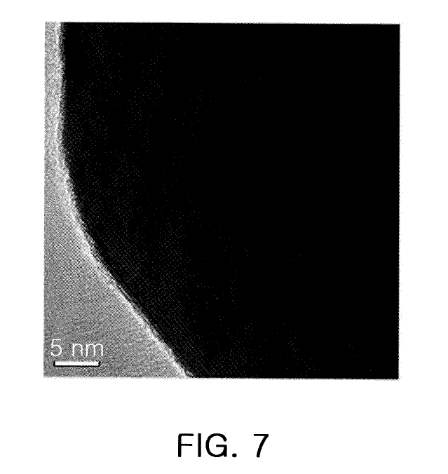

FIG. 7 is a high resolution transmission electron microscope (HRTEM) photograph of the barium titanate powder according to an embodiment of the present invention.

Referring to FIGS. 5 and 6, it can be seen that the barium titanate powder particle according to the embodiment of the present invention is doped with magnesium (Mg) and yttrium (Y) having a thickness of about 3 nm.

In addition, referring to FIG. 7, it can be seen that the barium titanate powder particle and the doping layer have the same crystal orientation, and it can be seen that a coating layer is not observed.

### Example 2

An organic solvent, such as, a sintering aid, a binder, ethanol, or the like, was added to the dielectric raw material powder particle prepared by the method of Example 1, and then subjected to wet mixing by using a ball mill, thereby preparing a ceramic slurry.

This ceramic slurry was molded into sheets by a doctor blade method in such a manner that a dielectric element thickness after sintering was 1 μm whereby rectangular green sheets are obtained.

Then, a conductive paste containing nickel (Ni) was screen-printed on the ceramic green sheets, and inner electrode patterns were alternately laminated on the ceramic green sheets to be subjected to compressing and then cutting.

The resultant structure was heated at the atmosphere, to remove the binder and subjected to sintering at the reducing atmosphere of 1100° C. A Cu paste (conductive paste) containing glass frit was applied to both cross sections of the ceramic capacitor element thus obtained, and then sintering was carried out thereon at a temperature of 800° C. at the atmosphere of N₂, whereby outer electrodes connected to inner electrodes are formed.

Electric properties of the multilayer ceramic capacitor manufactured by the above method were analyzed, and dielectric properties thereof at room-temperature were measured under the condition of 1 KHz and IR was measured under the condition of 6.3V.

### Comparative Example 1

Dy₂O₃ and MgO ultrafine-grain powder particles were added to a barium titanate powder particle of 90 nm, prepared by a hydrothermal synthesis method in the same composition as Example 1, and they were mixed through a wet mill.

After drying a slurry, a multilayer ceramic capacitor was manufactured by the same method as Example 2.

Electric properties of the manufactured multilayer ceramic capacitor was analyzed in the same method as Example 2.

Table 1 below shows electric properties of Example 2 and Comparative Example 1, which are compared and analyzed.

TABLE 1

| | Dielectric | Insulation | |
|---|---|---|---|
| | constant at | Resistance | Breakdown |
| | room-temperature | (IR) | voltage (BDV) |
| Example 2 | 2850 | 1.50E+09 | 82 |
| Comparative | 2400 | 5.10E+05 | 27 |
| example 1 | | | |

As shown in Table 1, it can be seen that Example 2 has a higher dielectric constant at room-temperature, as compared with a case of Comparative Example 1, and Example 2 is significantly superior than Comparative Example 1 in view of insulation resistance (IR) and breakdown voltage (BDV).

As a result, the multilayer ceramic capacitor according to the embodiments of the present invention may include the plural dielectric grains each having a surface on which the doping layer is formed, the doping layer being doped with the at least one material selected from the group consisting of alkaline earth elements and boron group elements and the rare earth element, such that the multilayer ceramic capacitor may have a dielectric constant at high room-temperature and excellent insulation resistance and withstand voltage properties, to allow for improvements in reliability thereof.

As set forth above, according to embodiments of the present invention, when a perovskite powder particle is synthesized by using a hydrothermal synthesis method, a doping layer doped with at least one material selected from the group consisting of alkaline earth elements and boron group elements and rare earth elements is formed on a surface of the perovskite powder particle, such that a dielectric composition having excellent reliability, dielectric properties, and electric properties can be fabricated.

Further, a multilayer ceramic electronic part manufactured by using the dielectric composition can have a high dielectric constant at room-temperature, and excellent insulation resistance and withstand voltage property, and thus, reliability thereof can be improved.

While the present invention has been shown and described in connection with the embodiments, it will be apparent to those skilled in the art that modifications and variations can be made without departing from the spirit and scope of the invention as defined by the appended claims.

What is claimed is:

1. A dielectric composition comprising: a perovskite powder particle having a surface on which a doping layer is formed, the doping layer being doped with at least one material selected from a group consisting of alkaline earth elements and boron group elements, and rare earth elements.

2. The dielectric composition of claim 1, wherein an average thickness of the doping layer is 0.1 to 10% of a diameter of the perovskite powder particle.

3. The dielectric composition of claim 1, wherein a standard deviation of an average thickness of the doping layer is 10% or less of a diameter of the perovskite powder particle.

4. The dielectric composition of claim 1, wherein the at least one material selected from a group consisting of alkaline earth elements and boron group elements and the rare earth elements, are at least one selected from a group consisting of nitrate, acetate, hydroxide, chloride, and perchlorate.

5. The dielectric composition of claim 1, wherein the rare earth elements are at least one selected from a group consisting of yttrium (Y), gadolinium (Gd), dysprosium (Dy), holmium (Ho), europium (Eu), erbium (Er) and ytterbium (Yb).

6. The dielectric composition of claim 1, wherein the alkaline earth elements are at least one selected from a group consisting of magnesium (Mg) and calcium (Ca).

7. The dielectric composition of claim 1, wherein the boron group elements are at least one selected from a group consisting of boron (B), aluminum (Al), gallium (Ga) and indium (In).

8. The dielectric composition of claim 1, wherein the perovskite powder particle is at least one selected from a group consisting of BaTiO₃, BaTiₓZr₁₋ₓO₃, BaₓY₁₋ₓTiO₃, BaₓDy₁₋ₓTiO₃, and Baₓ₋₁Ho₁₋ₓTiO₃ (0<x<1).

9. A method of fabricating a dielectric composition, the method comprising:
mixing a metal salt and a metal oxide to form a perovskite particle nucleus;
hydrothermally treating the perovskite particle nucleus to form a slurry;
mixing a solution in which at least one material selected from a group consisting of alkaline earth elements and boron group elements and rare earth elements are dissolved, into the slurry, and stirring the mixed solution; and
heating the mixed solution to obtain a perovskite powder particle having a surface on which a doping layer is formed, the doping layer being doped with the at least one material selected from a group consisting of alkaline earth elements and boron group elements and the rare earth element.

10. The method of claim 9, wherein an average thickness of the doping layer is 0.1 to 10% of a diameter of the perovskite powder particle.

11. The method of claim 9, wherein a standard deviation of an average thickness of the doping layer is 10% or less of a diameter of the perovskite powder particle.

12. The method of claim 9, wherein the at least one material selected from a group consisting of alkaline earth elements and boron group elements and the rare earth elements, are at least one selected from a group consisting of nitrate, acetate, hydroxide, chloride, and perchlorate.

13. The method of claim 9, wherein the rare earth elements are at least one selected from a group consisting of yttrium (Y), gadolinium (Gd), dysprosium (Dy), holmium (Ho), europium (Eu), erbium (Er) and ytterbium (Yb).

14. The method of claim 9, wherein the alkaline earth elements are at least one selected from a group consisting of magnesium (Mg) and calcium (Ca).

15. The method of claim 9, wherein the boron group elements are at least one selected from a group consisting of boron (B), aluminum (Al), gallium (Ga) and indium (In).

16. The method of claim 9, wherein the perovskite powder particle is at least one selected from a group consisting of BaTiO₃, BaTiₓZr₁₋ₓO₃, BaₓY₁₋ₓTiO₃, BaₓDy₁₋ₓTiO₃, and BaₓHo₁₋ₓTiO₃ (0<x<1).

17. The method of claim 9, wherein the doping layer and the perovskite powder particle have the same crystal lattice.

18. The method of claim 9, wherein the at least one material selected from a group consisting of alkaline earth elements and boron group elements and the rare earth elements have a content of 0.00001 to 3.0 parts by weight, based on 100 parts by weight of the perovskite powder particle.

19. A multilayer ceramic electronic component, comprising:
a ceramic main body including a dielectric layer; and
inner electrode layers disposed to face each other with the dielectric layer therebetween within the ceramic main body,
wherein the dielectric layer includes a plurality of dielectric grains each having a surface on which a doping layer is formed, the doping layer being doped with at least one material selected from a group consisting of alkaline earth elements and boron group elements and rare earth elements.

20. The multilayer ceramic electronic component of claim 19, wherein an average thickness of the doping layer is 0.1 to 10% of a diameter of each dielectric grain.

21. The multilayer ceramic electronic component of claim 19, wherein a standard deviation of an average thickness of the doping layer is 10% or less of a diameter of each dielectric grain.

22. The multilayer ceramic electronic component of claim 19, wherein the rare earth elements are at least one selected from a group consisting of yttrium (Y), gadolinium (Gd), dysprosium (Dy), holmium (Ho), europium (Eu), erbium (Er) and ytterbium (Yb).

23. The multilayer ceramic electronic component of claim 19, wherein the alkaline earth elements are at least one selected from a group consisting of magnesium (Mg) and calcium (Ca).

24. The multilayer ceramic electronic component of claim 19, wherein the boron group elements are at least one selected from a group consisting of boron (B), aluminum (Al), gallium (Ga) and indium (In).

25. The multilayer ceramic electronic component of claim 19, wherein each dielectric grain is at least one selected from a group consisting of BaTiO₃, BaTiₓZr₁₋ₓO₃, BaₓY₁₋ₓTiO₃, BaₓDy₁₋ₓTiO₃, and BaₓHo₁₋ₓTiO₃ (0<x<1).
